(19) United States
(12) Patent Application Publication
(10) Pub. No.: US 2011/0054818 A1
(43) Pub. Date: Mar. 3, 2011

(54) CHARGE-TRANSFER SENSOR WITH LOW POWER CONSUMPTION

(75) Inventors: Frederic Cantie, Toulouse (FR); Xavier Hourne, Cugnaux (FR)

(73) Assignee: CONTINENTAL AUTOMOTIVE FRANCE, Toulouse (FR)

(21) Appl. No.: 12/812,753

(22) PCT Filed: Dec. 5, 2008
(86) PCT No.: PCT/EP08/10333

§ 371 Date: Sep. 13, 2010

(30) Foreign Application Priority Data
Jan. 16, 2008 (FR) 08/00219

(51) Int. Cl. G06F 19/00; G01R 27/00

(52) U.S. Cl. 702/65

(57) ABSTRACT

The invention relates to a charge transfer-type sensor, including
a measuring device (Cx), for, during a succession of periodic time intervals (DT1), storing a quantity of electrical charges that is a function of a parameter to be measured,
an accumulation device (Cs) for discharging, between two intervals (DT1), the charges contained in the measuring device (Cx),
a switching device (M1) for, during the intervals (DT1), electrically connecting the measuring device (Cs) to a source (VCC) of electrical charges and for, outside the intervals (DT1), electrically connecting the measuring device (Cx) to the accumulation device (Cs),
a comparator (COMP) for comparing an electrical signal (VS) at the terminals of the accumulation device with a reference signal (VREF) and supplying an end-of-measurement signal (SD),
a microcontroller (MP) for, when it receives the end-of-measurement signal (SD), determining a value of the parameter to be measured,
a generator (GEN) of periodic command signals external to the microcontroller (MP), for controlling the switching device (M1) and
a counter (TIMER) external to the microcontroller (MP), for determining a number (NB) of time intervals (DT1) during which the measuring device (Cx) has stored charges before the comparator (COMP) supplies an end-of-measurement signal (SD),
   characterized in that the generator (GEN) of periodic command signals and/or the counter (TIMER) being constituents of an always-active portion of a microcontroller of which another portion is likely to be set to a standby mode.

The invention relates to a charge transfer-type sensor, comprising:
a measuring device for, during a succession of periodic time intervals, storing a quantity of electrical charges as a function of a parameter to be measured,
an accumulation device for discharging, between two intervals, the charges contained in the measuring device, and
a switching device for, during the intervals, electrically connecting the measuring device to a source of electrical charges and for, outside the intervals, electrically connecting the measuring device to the accumulation device,
a comparator for comparing an electrical signal at the terminals of the accumulation device with a reference signal and supplying an end-of-measurement signal, and
a microcontroller for determining a value of the parameter to be measured when it receives the end-of-measurement signal.

Such sensors are known, for example in order to determine the variation of a parameter to be measured, signifying, for example, an undesirable intrusion of a person into a room, the presence of a hand of a person on a door handle of an automotive vehicle or even a minimum/maximum level of liquid in a tank.

The measuring device is, for example, a capacitor, the capacitance of which varies significantly as a function of the parameter to be measured, or else a coil whose inductance varies significantly as a function of the parameter to be measured.

As it is known, the microcontroller controls the switching device, so that the microcontroller must imperatively remain active throughout the operation of the sensor. To remain active, the microcontroller must imperatively remain powered by an electrical energy source. This can cause problems concerning the lifespan of the electrical energy source, in particular for onboard applications, in the field of automotive vehicles for example, in which the energy source is an accumulator battery of necessarily finite capacity.

The invention proposes a sensor that does not have the limitations of the known sensors.

For this, the invention proposes a sensor, conforming to the above description, and also comprising: a generator of periodic command signals, external to the microcontroller for controlling the control device, and a counter external to the microcontroller, for determining a number of time intervals during which the measuring device has stored charges before the comparator supplies an end-of-measurement signal.

The counter, external to the microcontroller, consumes little energy. Moreover, the counter supplies the microcontroller with a value proportional to the parameter to be measured.

According to the invention, the microcontroller is of the type comprising a standby mode during which a proportion of the components of the microcontroller is likely to be off, another portion of the components of the microcontroller being constantly active. In this embodiment, the generator of periodic command signals and the counter of the sensor according to the invention can be components of the constantly active portion of the microcontroller.

Thus, during at least a part of the acquisition phase during which the measuring device is charged and then discharged, the microcontroller can be set to a standby mode so as to very greatly limit its electrical energy consumption. Then, when the comparator supplies an end-of-measurement signal, the microcontroller is reactivated, to determine the value of the parameter to be measured.

To limit the overall consumption of the sensor, the microcontroller is inactive as long as the end-of-measurement signal is inactive.

The invention will be better understood and other features and benefits will become apparent from reading the description of an example of an embodiment of a sensor according to the invention below. The description should be read in conjunction with the appended drawing in which:

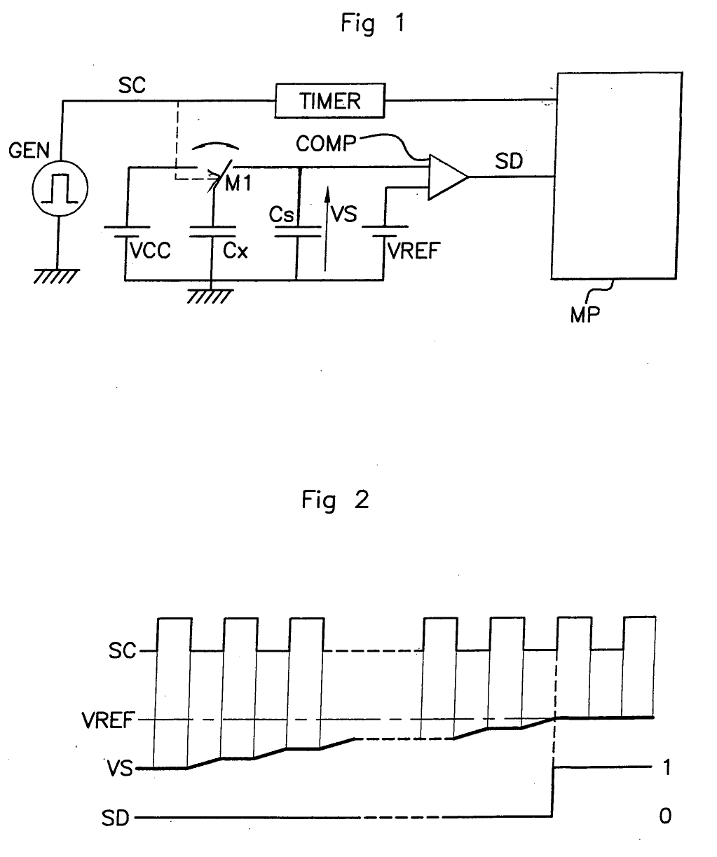

FIG. 1 is a diagram of a sensor according to the invention,

FIG. 2 is a timing diagram showing the trend over time of signals existing at the sensor of FIG. 1.

As an example, consideration is focused here on a sensor according to the invention installed on a door handle of a vehicle, for detecting the proximity of a hand of a user to said handle. The detection of a hand can then be used for example to unlock the door.

As stated previously, the sensor comprises a measuring device, a switching device, a comparator and a micro-controller.

In the example of FIG. 1, the measuring device is a measuring capacitor Cx. In the exemplary application envisaged, one of the two plates of the capacitor Cx is positioned in the handle of the door, so that the capacitance of the capacitor varies significantly according to the presence or the absence of a hand in the immediate vicinity of the handle.

The accumulation device is a capacitor Cs with a capacitance that is very much greater, for example of the order of one thousand times greater, than the capacitance of the measuring capacitor.

The switching device is, in the example of FIG. 1, a three-state switch M1, suitable for connecting the capacitor Cx either to a voltage source VCC, an accumulator battery of the vehicle in the application envisaged, or to the capacitor Cs.

The comparator COMP has a positive input connected to a terminal of the accumulation device Cs whose other terminal is connected to a ground of the sensor. The comparator COMP also has a negative input connected to a reference voltage source VREF. The comparator COMP supplies an end-of-measurement signal SD when the voltage at the terminals of the accumulation device becomes greater than the reference voltage VREF.

The sensor according to the invention also comprises a generator GEN of periodic command signals, external to the microcontroller MP, for controlling the switching device.

In the example of FIG. 1, the sensor also comprises a counter TIMER, incremented by the generator GEN, for example each time that the generator GEN produces an active signal SC.

During a so-called measurement initialization phase, the counter TIMER is set to zero and the accumulation device Cs is discharged.

The operation of the sensor is as follows.

The generator GEN produces the periodic signal SC (see FIG. 2). During a period T:
When the signal SC becomes active, the counter TIMER is incremented
When the signal SC is active, the measuring device is connected to the source VCC and is charged during a time interval DT1 during which the signal SC remains active.
When the signal SC is inactive, the measuring device is connected to the accumulation device and is discharged into said accumulation device during a time interval DT2, and the voltage VS increases.

During a first so-called acquisition phase, the measuring device is charged and then discharged several times in succession, for example of the order of a few hundred times. During this phase, all or some of the microcontroller MP is in standby mode to limit the energy consumption.

The acquisition phase ends when the comparator produces the end-of-measurement signal SD, when the voltage at the terminals of the accumulation device becomes greater than the reference voltage VREF.

When the end-of-measurement signal is produced, the microcontroller MP is reactivated. It reads the value

NB of the counter TIMER, and deduce therefrom the value of the capacitance of the measuring device Cx which is proportional to the value NB of the counter TIMER. Depending on the trend over time of the capacitance of the measuring device Cx, the detection algorithm implanted in the microcontroller MP can be used to determine whether a user has approached the door handle of the vehicle and shown intent to enter therein by moving his hand closer for example.

As can be seen in FIG. 1, in the context of the invention, the generator GEN and the counter TIMER are outside the microcontroller MP, so that the micro-controller MP can be set to standby mode throughout the whole acquisition phase and it is possible to have the microcontroller MP active only during a period T of the signal SC every NB periods.

In an alternative embodiment, the comparator COMP can be incorporated in the microcontroller MP, without in any way departing from the scope of the present invention.

1-2. (canceled)

3. A charge transfer-type sensor, comprising:
a measuring capacitor (Cx) for, during a succession of periodic time intervals (DT1), storing a quantity of electrical charges that is a function of a parameter to be measured,
an accumulation capacitor (Cs) for discharging, during a time interval (DT2), the charges contained in the measuring capacitor (Cx),
a switching device (M1) for, during the time intervals (DT1), electrically connecting the measuring capacitor (Cx) to a source (VCC) of electrical charges and for, during the time intervals (DT2), electrically connecting the measuring capacitor (Cx) to the accumulation capacitor (Cs),
a comparator (COMP), connected to a terminal of the accumulation capacitor (Cs) and to a reference signal (VREF), for comparing an electrical signal at the terminals of the accumulation capacitor (Cs) with the reference signal and supplying an end-of-measurement signal (SD), when the voltage at the terminals of the accumulation capacitor (Cs) becomes greater than the voltage of the reference signal (VREF),
a microcontroller (MP) for, when it receives the end-of-measurement signal (SD), determining a value of the parameter to be measured,
a generator (GEN) of periodic command signals external to the microcontroller (MP), for controlling the switching device (M1) and
a counter (TIMER) external to the micro-controller (MP), incremented by the generator (GEN) each time that it produces an active signal (SC), for determining a number (NB) of time intervals (DT1) during which the measuring capacitor device (Cx) stored charges before the comparator (COMP) supplied an end-of-measurement signal (SD),
characterized in that the generator (GEN) of periodic command signals and/or the counter (TIMER) are constituents of an always-active portion of the sensor, the microcontroller being set to a standby mode so as to very greatly limit its electrical energy consumption.

4. The sensor as claimed in claim 3, wherein the microcontroller (MP) is reactivated when the end-of-measurement signal (SD) is produced by the comparator (COMP).
